(19) United States
(12) Patent Application Publication
(10) Pub. No.: US 2024/0234583 A1
(43) Pub. Date: Jul. 11, 2024

(54) SEMICONDUCTOR DEVICE INCLUDING TWO-DIMENSIONAL MATERIAL AND ELECTRONIC DEVICE INCLUDING THE SEMICONDUCTOR DEVICE

(71) Applicant: Samsung Electronics Co., Ltd., Suwon-si (KR)

(72) Inventors: Junyoung KWON, Suwon-si (KR); Kyung-Eun BYUN, Suwon-si (KR); Minsu SEOL, Suwon-si (KR)

(73) Assignee: Samsung Electronics Co., Ltd., Suwon-si (KR)

(21) Appl. No.: 18/397,325

(22) Filed: Dec. 27, 2023

(30) Foreign Application Priority Data
Jan. 5, 2023 (KR) 10-2023-0001947

(51) Int. Cl. H01L 29/786; H01L 29/06; H01L 29/423; H01L 29/775

(52) U.S. Cl. CPC H01L 29/78696; H01L 29/0673; H01L 29/42392; H01L 29/775; H01L 29/7869

(57) ABSTRACT

Provided are a semiconductor device including a two-dimensional (2D) material and an electronic device including the semiconductor device. The semiconductor device may include a channel layer including a two-dimensional (2D) semiconductor material, a channel portion, and an extension portion on both sides of the channel portion, a source electrode and a drain electrode respectively on both sides of the channel layer, a gate electrode surrounding the channel portion, a first insulating layer between the channel portion of the channel layer and the gate electrode, and a second insulating layer on the extension portion of the channel layer. The second insulating layer may include a different material than a material of the first insulating layer. The second insulating layer may include a n-type dopant or p-type dopant. A dopant in the extension portion may be the same as a dopant in the second insulating layer.

### CROSS-REFERENCE TO RELATED APPLICATIONS

This application is based on and claims priority under 35 U.S.C. § 119 to Korean Patent Application No. 10-2023-0001947, filed on Jan. 5, 2023 in the Korean Intellectual Property Office, the disclosure of which is incorporated by reference herein in its entirety.

### BACKGROUND

### 1. Field

The disclosure relates to a semiconductor device including a two-dimensional material and an electronic device including the semiconductor device.

### 2. Description of the Related Art

A transistor, which is a semiconductor device operating as an electric switch, has been used for various semiconductor products such as memories, driving integrated circuits (ICs), etc. As the size of semiconductor devices decreases, the number of semiconductor devices that may be integrated on a single wafer may increase and a driving speed of the semiconductor devices may also increase. Thus, research for reducing the size of semiconductor devices has been actively conducted.

Recently, as a way to reduce the sizes of semiconductor devices, research using two-dimensional (2D) materials has been conducted. Due to their stable and superior properties even in the case of a small thickness of about 1 nm or less, 2D materials are in the limelight as materials capable of overcoming limitations of on performance degradation due to size reduction of semiconductor devices.

A structure of a transistor used in a semiconductor device has evolved from a sheet to a gate-all-around (GAA) structure via a fin field-effect transistor (FinFET) structure. A multi-bridge channels (MBC)-FET, which is a type of a GAA structure that has just begun to be used, responds to deterioration caused by a short channel effect corresponding to an increase of integration of the semiconductor device through a structure wherein plate thin channels are vertically stacked.

### SUMMARY

Provided are a semiconductor device including a two-dimensional (2D) material and an electronic device including the semiconductor device.

Additional aspects will be set forth in part in the description which follows and, in part, will be apparent from the description, or may be learned by practice of the presented embodiments of the disclosure.

According to an example embodiment, a semiconductor device may include a channel layer including a two-dimensional (2D) semiconductor material, a channel portion, and an extension portion on both sides of the channel portion, a source electrode and a drain electrode on both sides of the channel layer, respectively, a gate electrode surrounding the channel portion, a first insulating layer between the channel portion of the channel layer and the gate electrode, and a second insulating layer on an extension portion of the channel layer. A material of the second insulating layer may be different from a material of the first insulating layer. The second insulating layer may include at least one of an n-type dopant or a p-type dopant. A dopant in the extension portion may be the same as a dopant included in the second insulating layer.

In some embodiments, the first insulating layer may surround the channel portion, and the second insulating layer may surround the extension portion.

In some embodiments, the second insulating layer may include at least one of an aluminum oxide, a hafnium oxide, a zirconium oxide, or a compound thereof.

In some embodiments, the second insulating layer may include an insulating material having a dielectric constant less than a dielectric constant of the first insulating layer.

In some embodiments, the second insulating layer may include an insulating material having a band offset of about 200 meV or less with the 2D semiconductor material.

In some embodiments, the second insulating layer may include an insulating material having a band offset of about 50 meV or greater with the 2D semiconductor material.

In some embodiments, the channel layer may include two or more channel layers.

In some embodiments, the semiconductor device may further include at least one supporting layer on the channel layer.

In some embodiments, the supporting layer may include at least one of a hafnium oxide or an aluminum oxide.

In some embodiments, the 2D semiconductor material may include an n-type or p-type 2D semiconductor material.

In some embodiments, the n-type 2D semiconductor material may include at least one of MoS₂, MoSe₂, MoTe₂, or WS₂.

In some embodiments, the p-type 2D semiconductor material may include at least one of WSe₂, MoTe₂, or PtSe₂.

In some embodiments, the 2D semiconductor device may include transition metal dichalcogenide (TMD).

In some embodiments, the TMD may include one of molybdenum (Mo), tungsten (W), niobium (Nb), vanadium (V), tantalum (Ta), titanium (Ti), zirconium (Zr), hafnium (Hf), technetium (Tc), and rhenium (Re), and a chalcogen element selected from sulfur (S), selenium (Se), and tellurium (Te).

In some embodiments, the 2D semiconductor material may include black phosphorus.

According to an example embodiment, a semiconductor device may include a channel layer including a two-dimensional (2D) semiconductor material, a channel portion, and an extension portion on both sides of the channel portion, a source electrode and a drain electrode on both sides of the channel layer, respectively, a gate electrode on the channel portion, a first insulating layer between the channel portion of the channel layer and the gate electrode, and a second insulating layer on the extension portion of the channel layer. A material of the second insulating layer may be different from a material of the first insulating layer.

In some embodiments, the second insulating layer may include an insulating material having a band offset of about 200 meV or less with the 2D semiconductor material.

In some embodiments, the second insulating layer may include an insulating material having a band offset of about 50 meV or greater with the 2D semiconductor material.

According to an example embodiment, an electronic device may include any one of the above-described semiconductor devices.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a semiconductor device according to an embodiment;

FIG. 2 is a cross-sectional view showing a semiconductor device according to another embodiment;

FIG. 3 is a cross-sectional view showing a semiconductor device according to another embodiment;

FIGS. 4A to 4F are views for describing a method of manufacturing a semiconductor device according to an embodiment;

FIGS. 5A to 5F are views for describing a method of manufacturing a semiconductor device according to an embodiment;

FIG. 6 is a cross-sectional view showing a semiconductor device according to another embodiment;

FIG. 7 is a cross-sectional view showing a semiconductor device according to another embodiment;

FIG. 8 is a cross-sectional view showing a semiconductor device according to another embodiment;

FIG. 9 is a cross-sectional view showing a semiconductor device according to another embodiment;

FIG. 10 is a block diagram of an electronic device according to an embodiment;

FIG. 11 is a block diagram of an electronic device according to another embodiment; and

FIGS. 12 and 13 are conceptual views schematically showing a device architecture applicable to an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, various embodiments disclosed herein will be described in detail with reference to the accompanying drawings. In the drawings, like reference numerals denote like components, and sizes of components in the drawings may be exaggerated for convenience of explanation. Meanwhile, embodiments to be described are merely examples, and various modifications may be made from such embodiments.

When an expression “above” or “on” may include not only “directly on/under/at left/right contactually”, but also “on/under/at left/right contactlessly”. Singular forms include plural forms unless apparently indicated otherwise contextually. When a portion is referred to as “comprises” a component, the portion may not exclude another component but may further include another component unless stated otherwise.

The use of the terms of “the above-described” and similar indicative terms may correspond to both the singular forms and the plural forms. When there is an explicit description of the order of operations of the method or there is no description contrary thereto, these operations may be performed in an appropriate order and the order is not necessarily limited to the described order.

The term used herein such as “unit” or “module” indicates a unit for processing at least one function or operation, and may be implemented in hardware, software, or in a combination of hardware and software.

Terms such as first, second, and the like may be used to describe various elements, but the elements should not be limited to those terms. These terms may be used to distinguish one element from another element.

Connections of lines or connection members between components shown in the drawings are illustrative of functional connections and/or physical or circuit connections, and in practice, may be represented as alternative or additional various functional connections, physical connections, or circuit connections.

The use of all examples or example terms is only to describe technical spirit in detail, and the scope is not limited by these examples or terms unless limited by the claims.

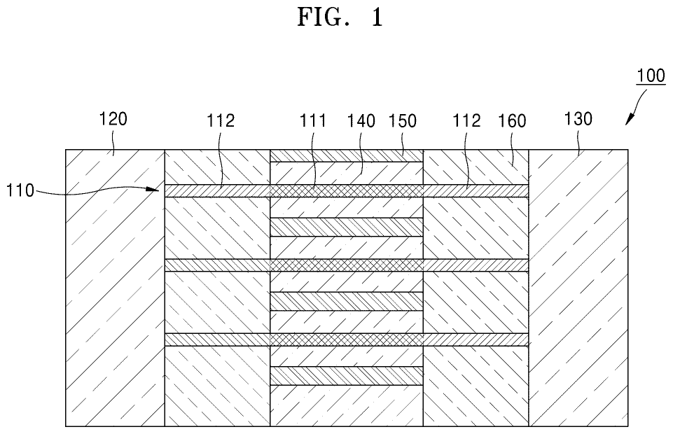

FIG. 1 is a cross-sectional view showing a semiconductor device according to an embodiment.

A semiconductor device 100 shown in FIG. 1 may include, for example, a field effect transistor (FET).

With technical development, the semiconductor device 100 has evolved from a sheet to a gate-all-around (GAA) structure through a fin structure to manufacture a high-integration transistor. A multi-bridge channel (MBC) FET is a type of a GAA transistor structure and may mean a structure in which a plurality of thin channel layers in a sheet form are vertically stacked.

Referring to FIG. 1, a channel layer 110 including a two-dimensional (2D) semiconductor material may be provided, and each channel layer 110 may include a channel portion 111 and an extension portion 112. A source electrode 120 and a drain electrode 130 may be on both sides of the channel layer 110. The gate electrode 150 may be formed to surround the channel portion 111 included in the channel layer 110.

The channel layer 110 may include a 2D semiconductor material. The channel layer 110 may be formed in a nanosheet form that may include a 2D semiconductor material. The 2D material may mean a material having a layered structure in which constituent atoms are two-dimensionally coupled. The 2D material having semiconductor characteristics may have an electrical property and maintain high mobility without a large change in characteristics thereof even when the thickness thereof decreases to a nanoscale.

The 2D semiconductor material may include a material having a band gap of about 0.1 eV to about 3.0 eV. For example, the 2D semiconductor material may include transition metal dichalcogenide (TMD), black phosphorus, or graphene. However, example embodiments are not limited thereto.

TMD, which is a 2D material having semiconductor characteristics, may be a compound of a transition metal and a chalcogen element. Herein, the transition metal may include at least one of, for example, molybdenum (Mo), tungsten (W), niobium (Nb), vanadium (V), tantalum (Ta), titanium (Ti), zirconium (Zr), hafnium (Hf), carbon monoxide (Co), technetium (Tc), and rhenium (Re), and the chalcogen element may include at least one of, for example, sulfur (S), selenium (Se), and tellurium (Te). As a detailed example, TMD may include MoS₂, MoSe₂, MoTe₂, WS₂, WSe₂, WTe₂, ZrS₂, ZrSe₂, HfS₂, HfSe₂, NbSe₂, ReSe₂, and so forth. However, example embodiments are not limited thereto. Black phosphorus may be a semiconductor material having a structure in which phosphorus (P) atoms are two-dimensionally coupled.

The 2D semiconductor material may be doped with a p-type dopant or an n-type dopant to adjust mobility, and the doping may be performed by a second insulating layer 160 described below. The channel layer 110 may have a monolayer or multilayer structure in which each layer may have a thickness in an atomic level. The channel layer 110 may include, for example, one layer to ten layers, which is an embodiment, but example embodiments are not limited thereto.

There may be two or more channel layers 110, each of which may be as described above.

A first insulating layer 140 may be between the channel portion 111 and the gate electrode 150, and may include a material that is different from that of a second insulating layer 160 described below.

The first insulating layer 140 may surround the channel portion 111 and to surround all four sides of the channel portion 111. However, example embodiments are not limited thereto and the first insulating layer 140 may be formed to cover a part of an outer surface of the channel portion 111.

The first insulating layer 140 may include, but not limited to, a silicon nitride, etc.

The second insulating layer 160 may be on the extension portion 112 included in the channel layer 110 and may be doped with a certain dopant. The dopant may include at least one of an n-type dopant or a p-type dopant.

The second insulating layer 160 may be formed to surround the extension portion 112 or four sides thereof, but without being limited thereto, to cover a part of an outer surface of the extension portion 112.

The second insulating layer 160 may include at least one of an aluminum oxide, a hafnium oxide, a zirconium oxide, or a compound thereof, but without being limited thereto, may include various materials available as an insulating layer.

The second insulating layer 160 may include an insulating material having a dielectric constant or permittivity less than that of the first insulating layer 140. The insulating material of the second insulating layer 160 has a relatively low dielectric constant (or permittivity), thereby minimizing interference between source/drain electrodes and a gate electrode. When the dielectric constant of the insulating material is low, polarization of the insulating layer may occur relatively less, which minimizes a current change or current flow with respect to a voltage and thus minimize interference between source/drain electrodes and a gate electrode.

The second insulating layer 160 and the extension portion 112 included in the channel layer 110 may include different materials having different energy bands. When the different materials form hetero junction, a band offset may occur in a process of balancing the energy bands due to different conduction bands and valence bands of the different materials. That is, the band offset may refer to a state in which ends of the energy bands of the hetero-junction materials are not smoothly connected and the energy bands for electrons and holes are asymmetric.

The second insulating layer 160 may form hetero junction with the 2D semiconductor material included in the extension portion 112 and the energy bands are unbalanced witch each other, causing a band offset, and the second insulating layer 160 may include an insulating material having a band offset of about 200 meV or less with the 2D semiconductor material. Moreover, the second insulating layer 160 may include, but not limited to, an insulating material having a band offset of about 50 meV or greater with the 2D semiconductor material. As the energy band differs with the 2D semiconductor material, a band offset between the second insulating layer 160 and the 2D semiconductor material may differ with the 2D semiconductor material.

The second insulating layer 160 may include at least one of an n-type dopant or a p-type dopant.

The second insulating layer 160 doped with one of the n-type dopant and the p-type dopant may dope the extension portion 112 through charge transfer to the extension portion 112 included in the channel layer 110. Depending on a band structure of an adjacent material, an electron or a hole may be transferred or received, and such a transferred electron or hole may contribute to a carrier density in the extension portion 112 of the channel layer 110 based on the 2D material.

The 2D semiconductor material of the extension portion 112 may be doped by changing a type of an oxide of the second insulating layer 160 or band alignment of the extension portion 112 between the second insulating layer 160 and the extension 112 being adjacent to each other.

More specifically, the 2D semiconductor material may be doped with a p-type dopant or an n-type dopant in the foregoing manner rather than ion implantation.

A source of the p-type dopant may include, for example, ionic liquid, such as NO₂BF₄, NOBF₄, NO₂SbF₆, etc., an acidic compound, such as HCl, H₂PO₄, CH₃COOH, H₂SO₄, HNO₃, etc., an organic compound, such as dichlorodicyanoquinone (DDQ), oxone, dimyristoylphosphatidylinositol (DMPI), trifluoromethanesulfoneimide, etc. Alternatively, the source of the p-type dopant may include, for example, HPtCl₄, AuCl₃, HAuCl₄, AgOTf (silver trifluoromethanesulfonate), AgNO₃, H₂PdCl₆, Pd(OAc)₂, Cu(CN)₂, or the like.

The source of the n-type dopant may include, for example, a reduction product of a substituted or unsubstituted nicotinamide, a reduction product of a compound which is chemically bound to a substituted or unsubstituted nicotinamide, and a compound including at least two pyridinium moieties in which a nitrogen atom of at least one of the pyridinium moieties is reduced. For example, the source of the n-type dopant may include nicotinamide mononucleotide-H (NMNH), nicotinamide adenine dinucleotide-H (NADH), nicotinamide adenine dinucleotide phosphate-H (NADPH), or viologen. Alternatively, the source of the n-type dopant may include polymer such as polyethylenimine (PEI), etc. Alternatively, the n-type dopant may include alkali metal such as K, Li, etc. Meanwhile, the above-described materials of the p-type dopant and the n-type dopant are examples, and various other materials may be used as dopants.

The gate electrode 150 may include a metal material or a conductive oxide. The metal material may include, for example, at least one selected from Au, Ti, TiN, TaN, W, Mo, WN, Pt, and Ni. The conductive oxide may include, for example, indium tin oxide (ITO), indium zinc oxide (IZO), etc. However, this is merely an example.

The source electrode 120 and the drain electrode 130 may be on both sides of the gate electrode 150. The source electrode 120 and the drain electrode 130 may include, but not limited to, a metal material, etc., having excellent electric conductivity, such as argentum (Ag), aurum (Au), platinum (Pt), copper (Cu), etc.

In an existing Si-based semiconductor device, mobility is lowered and threshold voltage distribution increases with reduction of a channel thickness, and performance degradation due to a short channel effect may become severe with reduction of a channel length, which may result in a limitation in size reduction of the semiconductor device.

The semiconductor device 100 according to the current embodiment may have superior performance even in a small thickness of about 1 nm or less and reduce a short channel effect, by using the 2D semiconductor material as a channel, thereby overcoming the limitation of performance degradation caused by size reduction of the semiconductor device 100.

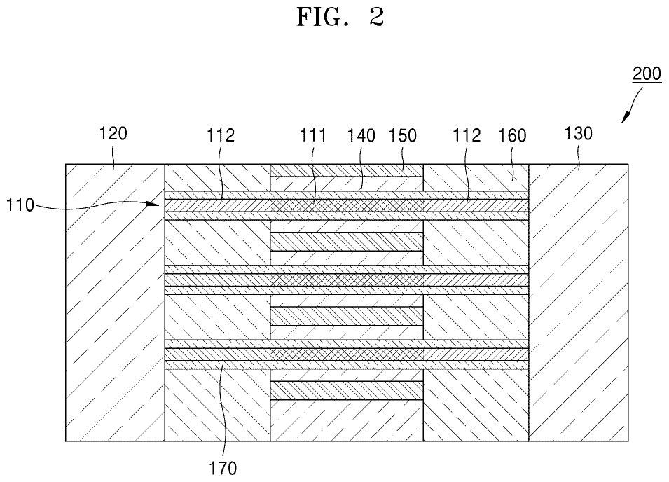

FIG. 2 is a cross-sectional view showing a semiconductor device 200 according to another embodiment.

Referring to FIG. 2, the semiconductor device 200 will be described which further includes at least one supporting layer 170 in addition to the channel layer 110 of the semiconductor device 100 described with reference to FIG. 1.

To support the channel layer 110 including a thin 2D material or a 2D material layer in a process of manufacturing a field-effect transistor (FET) including a multi-bridge channel (MBC), the supporting layer 170 may be on the channel layer 110 to serve structurally complementarily.

The supporting layer 170 may include, but not necessarily limited to, at least one of a hafnium oxide or an aluminum oxide.

Due to structural characteristics of further including the supporting layer 170, the second insulating layer 160 may not directly contact the channel layer 110 or the extension portion 112.

The doping through charge transfer of a type described with reference to FIG. 1 may occur between adjacent different material layers, but the supporting layer 170 of FIG. 2 is very thin and thus the doping of the type described with reference to FIG. 1 may be used therefor. Such a type may be referred to as remote doping, and different physical layers that are not physically adjacent to each other may be subject to charge transfer doping through tunneling, but various types of remote doping may be possible without being necessarily limited to the tunneling type.

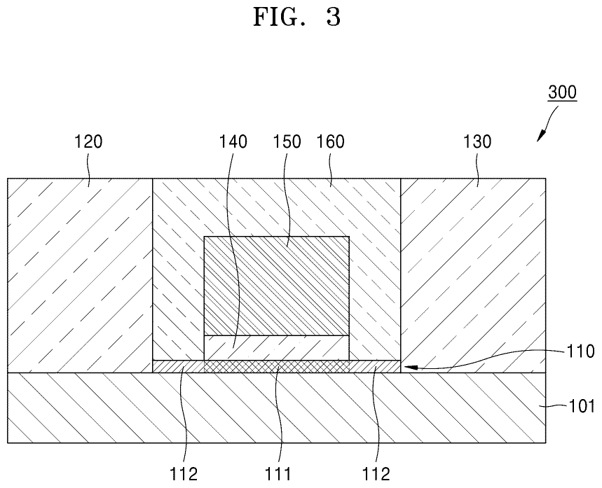

FIG. 3 is a cross-sectional view showing a semiconductor device 300 according to another embodiment.

Referring to FIG. 3, the channel layer 110 including a 2D semiconductor material may be provided, and the channel layer 110 may include the channel portion 111 and the extension portion 112. The source electrode 120 and the drain electrode 130 may be on both sides of the channel layer 110. The gate electrode 150 may be formed on the channel portion 111 included in the channel layer 110. The first insulating layer 140 may be between the channel portion 111 and the gate electrode 150, and the second insulating layer 160 including a material that is different from that of the first insulating layer 140 may be on the extension portion 112.

The channel layer 110 included in the semiconductor device 300 described with reference to FIG. 3 may be one material layer, and may include a 2D semiconductor material, and a detailed description of the channel layer 110 may refer to FIG. 1.

Hereinbelow, a method of manufacturing the semiconductor device 100 according to the above-described embodiment will be described.

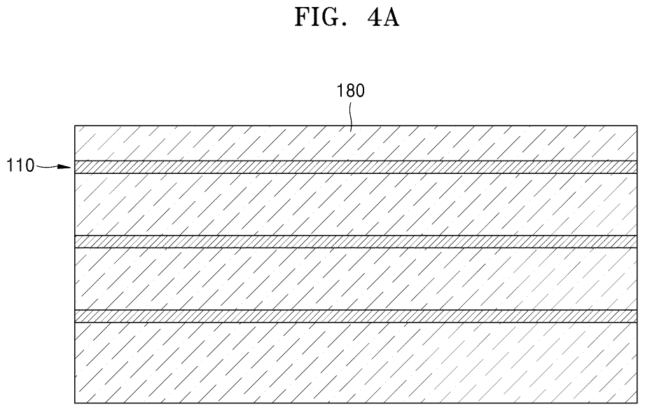

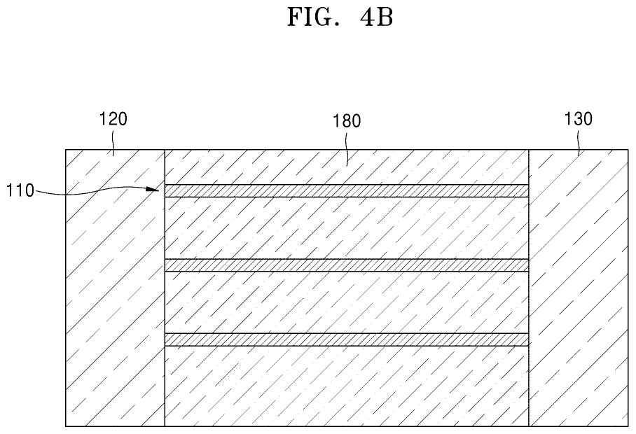

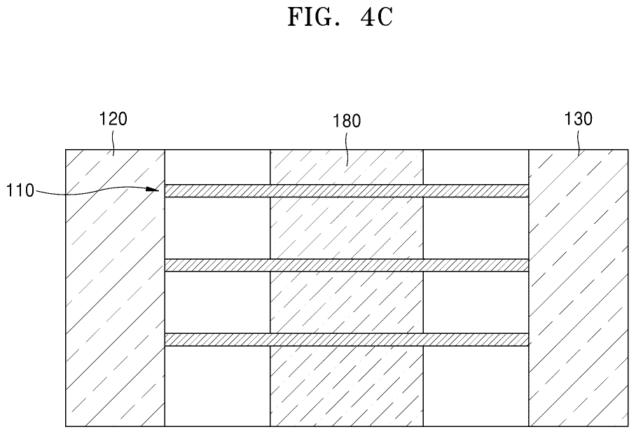

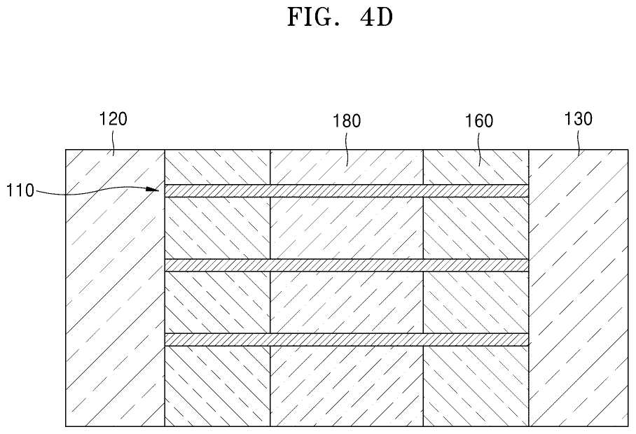

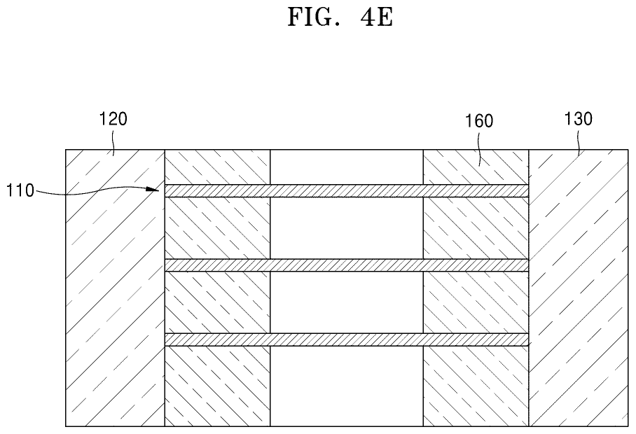

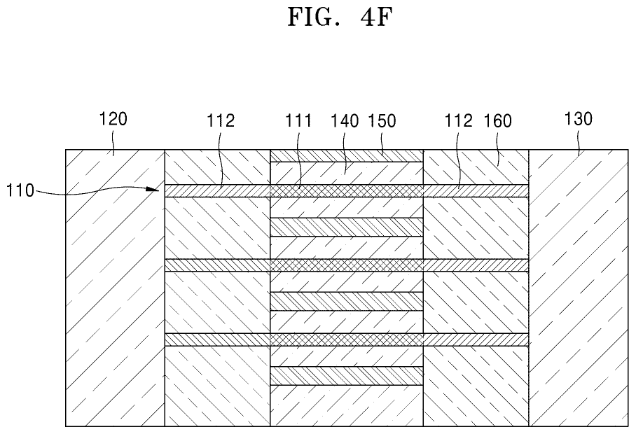

FIGS. 4A to 4F are views for describing a method of manufacturing a semiconductor device according to an embodiment.

Referring to FIG. 4A, the plurality of channel layers 110 and a plurality of sacrificial layers 180 may be stacked alternately. Each of the plurality of channel layers 110 may include a 2D semiconductor material as described with reference to FIG. 1.

The 2D semiconductor material may include a material having a band gap of about 0.1 eV to about 3.0 eV. For example, the 2D semiconductor material may include TMD or phosphorus black. However, example embodiments are not limited thereto.

The plurality of sacrificial layers 180 may include a material used in a process of manufacturing a semiconductor device and may include a material that may be etched by etching. For example, the sacrificial layer 180 may include, but not necessarily limited to, SiO₂, and may include various materials that are easy to remove by etching.

The plurality of channel layers 110 and the plurality of sacrificial layers 180 may be formed by deposition growth. Deposition of the plurality of channel layers 110 and the plurality of sacrificial layers 180 may be performed by, for example, chemical vapor deposition (CVD), physical vapor deposition (PVD), etc., but this is merely an example.

Referring to FIG. 4B, the plurality of channel layers 110 and the plurality of sacrificial layers 180 may be stacked alternately, and the source electrode 120 and the drain electrode 130 may be arranged on both sides of the plurality of channel layers 110 and sacrificial layers 180. The source electrode 120 and the drain electrode 130 are described above.

Referring to FIG. 4C, some (e.g., portions) of the plurality of sacrificial layers 180 may be removed by etching. Etching may include wet etching using hydrofluoric acid liquid and dry etching using a tetrafluoromethane gas. In addition, sputtering etching using a sputtering method may be provided. However, example embodiments are not limited thereto.

When the sacrificial layer 180 is etched, an empty space may be formed between an unetched sacrificial layer 180 and the source electrode 120/the drain electrode 130.

Referring to FIG. 4D, the second insulating layer 160 may be deposited on the empty space generated in a sacrificial layer region removed by etching in FIG. 4C. Deposition of the second insulating layer 160 may be performed by, for example, CVD, PVD, etc., but this is merely an example.

Referring to FIG. 4E, all portions of the remaining sacrificial layer 180 may be removed by etching. Etching is as described above.

An empty space may be formed in a region of the sacrificial layer 180 removed by etching.

Referring to FIG. 4F, the first insulating layer 140 and the gate electrode 150 may be deposited in the empty space formed by removing the sacrificial layer 180 through etching. Deposition of the first insulating layer 140 and the gate electrode 150 may be performed by, for example, CVD, PVD, atomic layer deposition, etc., but this is merely an example.

The first insulating layer 140 may serve as a gate insulating layer between the gate electrode 150 and the channel layer 110. The first insulating layer 140 and the gate electrode 150 are described above.

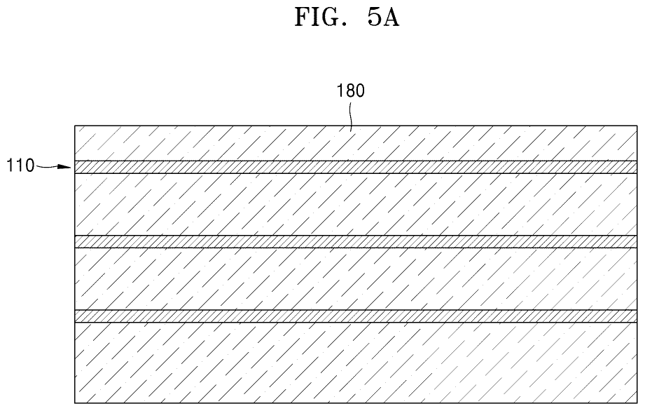

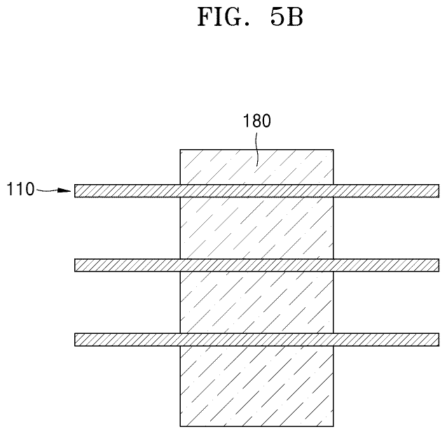

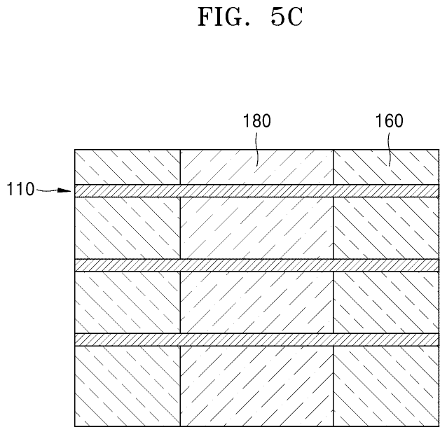

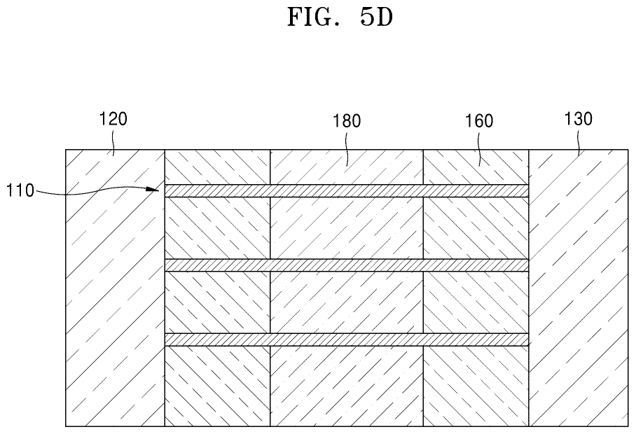

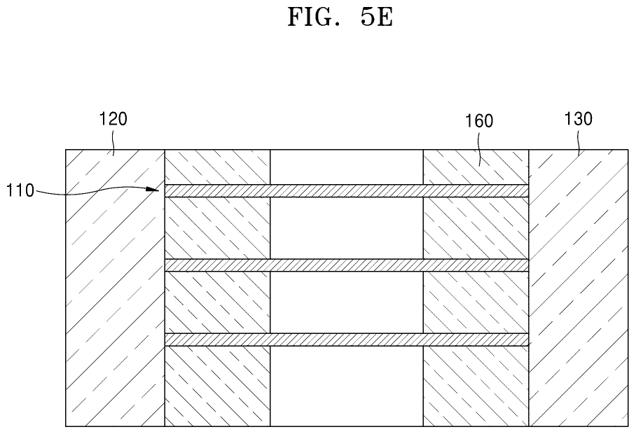

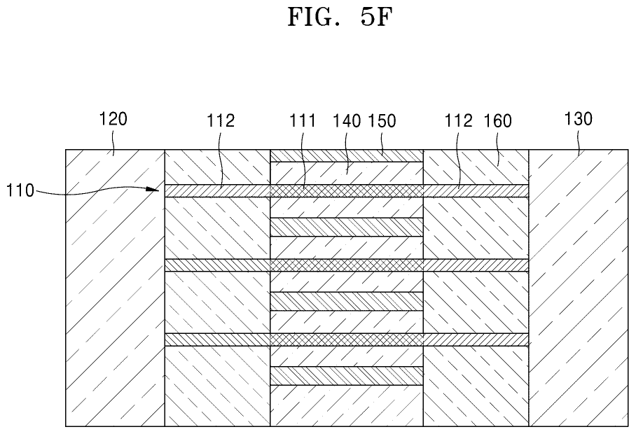

FIGS. 5A to 5F are views for describing a method of manufacturing a semiconductor device according to an embodiment.

Referring to FIG. 5A, the plurality of channel layers 110 and the plurality of sacrificial layers 180 may be stacked alternately. Each of the plurality of channel layers 110 may include a 2D semiconductor material as described with reference to FIG. 1.

The 2D semiconductor material may include a material having a band gap of about 0.1 eV to about 3.0 eV. For example, the 2D semiconductor material may include TMD or phosphorus black. However, example embodiments are not limited thereto.

The plurality of sacrificial layers 180 may include a material used in a process of manufacturing a semiconductor device and may include a material that may be etched by etching. For example, the sacrificial layer 180 may include, but not necessarily limited to, SiO₂, and may include various materials that are easy to remove by etching.

The plurality of channel layers 110 and the plurality of sacrificial layers 180 may be formed by deposition growth. Deposition of the plurality of channel layers 110 and the plurality of sacrificial layers 180 may be performed by, for example, CVD, PVD, etc., but this is merely an example.

Referring to FIG. 5B, some of the plurality of sacrificial layers 180 may be removed by etching. Etching may include wet etching using hydrofluoric acid liquid and dry etching using a tetrafluoromethane gas. In addition, sputtering etching using a sputtering method may be provided. However, example embodiments are not limited thereto.

Referring to FIG. 5C, the second insulating layer 160 may be deposited in an empty space formed by etching. A deposition method is as described above.

The second insulating layer 160 may include at least one of an aluminum oxide, a hafnium oxide, a zirconium oxide, or a compound thereof, as described above, but may include various materials available as an insulating layer without being limited thereto.

The second insulating layer 160 may include an insulating material having a dielectric constant or permittivity less than that of the first insulating layer 140. The insulating material of the second insulating layer 160 has a relatively low dielectric constant (or permittivity), thereby minimizing interference between source/drain electrodes and a gate electrode. When the dielectric constant of the insulating material is low, polarization of the insulating layer may occur relatively less, which minimizes a current change or current flow with respect to a voltage and thus minimize interference between source/drain electrodes and a gate electrode.

Referring to FIG. 5D, the source electrode 120 and the drain electrode 130 may be formed on both sides of the second insulating layer 160. The source electrode 120 and the drain electrode 130 are described above.

Referring to FIG. 5E, the entire remaining unremoved sacrificial layer may be removed by etching. Etching is as described above.

An empty space may be formed in a region of the sacrificial layer 180 removed by etching.

Referring to FIG. 5F, the gate electrode 150 and the first insulating layer 140 may be formed in the empty space, and the first insulating layer 140 may be a gate insulating layer between the gate electrode 150 and the channel layer 110.

Deposition of the first insulating layer 140 and the gate electrode 150 may be performed by, for example, CVD, PVD, atomic layer deposition, etc., but this is merely an example.

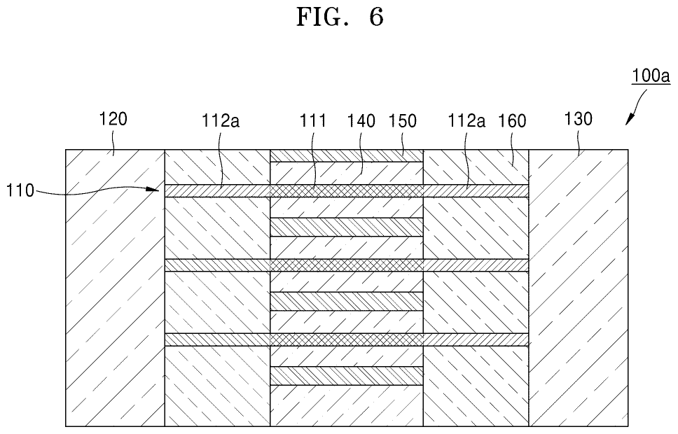

FIG. 6 is a cross-sectional view showing a semiconductor device 100a according to another embodiment.

Referring to FIG. 6, the second insulating layer 160 included in the channel layer 110 may include an n-type dopant. An extension portion 112a arranged adjacent to the second insulating layer 160 may be doped with an n-type dopant.

There may be two or more channel layers 110 and doped extension portions 112a included in the channel layers 110, and the channel layer 110 and the extension portion 112a may be arranged in a line in a vertical direction (a Z direction). However, the channel layer 110 and the extension portion 112a are not necessarily plural.

Although not illustrated, the semiconductor device 100a may be modified further to include the supporting layer 170 (see FIG. 2) between the second insulating layer 160 and the extension portion 112a and between the first insulating layer 140 and the channel portion 111. The supporting layer 170 may be on an upper surface of the extension portion 112a and a lower surface of the extension portion 112a. The supporting layer 170 may be on an upper surface of the channel portion 111 and may be on a lower surface of the channel portion 111.

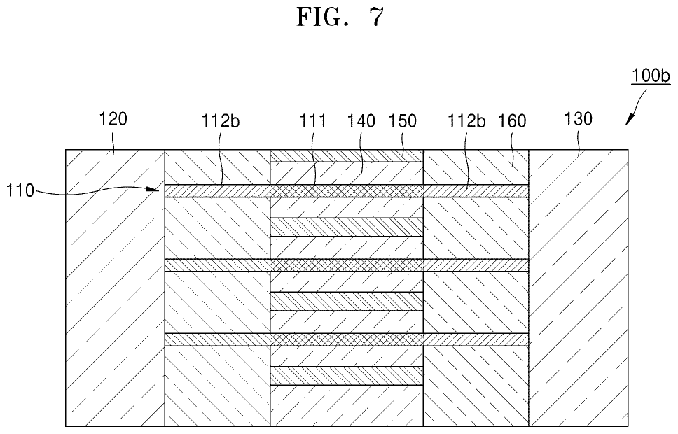

FIG. 7 is a cross-sectional view showing a semiconductor device 100b according to another embodiment.

Referring to FIG. 7, the second insulating layer 160 included in the channel layer 110 may include a p-type dopant. An extension portion 112b arranged adjacent to the second insulating layer 160 may be doped with a p-type dopant.

There may be two or more channel layers 110 and doped extension portions 112b included in the channel layers 110, and the channel layer 110 and the extension portion 112b may be arranged in a line in the vertical direction (the Z direction). However, the channel layer 110 and the extension portion 112b are not necessarily plural.

Although not illustrated, the semiconductor device 100b may be modified further to include the supporting layer 170 (see FIG. 2) between the second insulating layer 160 and the extension portion 112b and between the first insulating layer 140 and the channel portion 111. The supporting layer 170 may be on an upper surface of the extension portion 112b and a lower surface of the extension portion 112b. The supporting layer 170 may be on an upper surface of the channel portion 111 and may be on a lower surface of the channel portion 111.

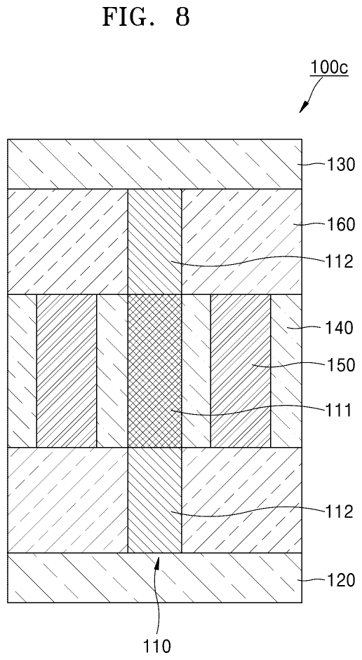

FIG. 8 is a cross-sectional view showing a semiconductor device 100c according to another embodiment.

Referring to FIG. 8, the source electrode 120 and the drain electrode 130 may be included, between which the channel portion 111, and the extension portion 112 of the channel layer 110 described with reference to FIG. 1 may be arranged in the vertical direction (the Z direction). A semiconductor device structured as described above may include a vertical channel transistor (VCT) structure.

The other components of the semiconductor device of FIG. 8 may be the same as described with reference to FIG. 1.

While FIG. 8 shows a semiconductor device including one vertical channel transistor (VCT) between two gate electrodes 150 spaced apart from the channel layer 110, example embodiments are not limited thereto.

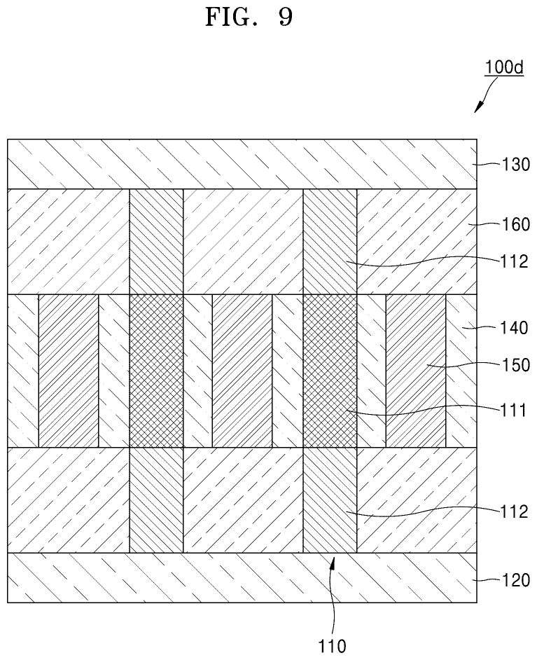

FIG. 9 is a cross-sectional view showing a semiconductor device 100d according to another embodiment.

As depicted in FIG. 9, a semiconductor device 100d may include a plurality of vertical channel transistors (VCTs), each having a channel layer 110 extending between the source electrode 120 and the drain electrode 130 with the channel portion 110 between a pair of gate electrodes 150.

The above-described semiconductor devices 100, 100a, 100b, 100c, 100d, 200, and 300 may be applied to a memory device, for example, a dynamic random access memory (DRAM) device, etc. The memory device may have a structure in which the above-described semiconductor devices 100, 100a, 100b, 100c, 100d, 200, and 300 and a capacitor are electrically connected. The semiconductor devices 100, 100a, 100b, 100c, 100d, 200, and 300 may be applied to various electronic devices. For example, the above-described semiconductor devices 100, 100a, 100b, 100c, 100d, 200, and 300 may be used for arithmetic operations, program execution, temporary data retaining, etc., in an electronic device such as a mobile device, a computer, a laptop computer, a sensor, a network device, a neuromorphic device, etc.

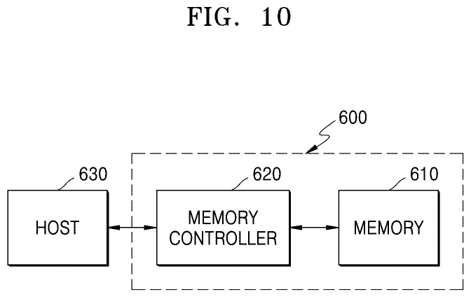

FIG. 10 is a block diagram of an electronic device 600 according to an embodiment.

Referring to FIG. 10, the electronic device 600 may include a memory 610 and a memory controller 620. The memory controller 620 may control the memory 610 for data reading from the memory 610 and/or data writing to the memory 610, in response to a request of a host 630. The memory 610 may include a semiconductor device according to the above-described embodiments.

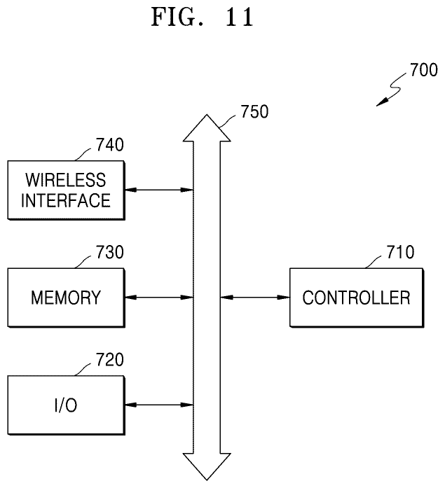

FIG. 11 is a block diagram of an electronic device 700 according to an embodiment.

Referring to FIG. 11, the electronic device 700 may constitute a wireless communication device or a device capable of transmitting and/or receiving information in a wireless environment. The electronic device 700 may include a controller 710, an input/output device I/O 720, a memory 730, and a wireless interface 740, which are connected to one another through a bus 750.

The controller 710 may include at least one of a microprocessor, a digital signal processor, or a processing device similar thereto. The input/output device 720 may include at least one of a keypad, a keyboard, or a display. The memory 730 may be used to store a command executed by the controller 710. For example, the memory 730 may be used to store user data. The electronic device 700 may use the wireless interface 740 to transmit/receive data through a wireless communication network. The wireless interface 740 may include an antenna and/or a wireless transceiver. In some embodiments, the electronic device 700 may be used in a communication interface protocol of a third-generation communication system, such as code division multiple access (CDMA), global system for mobile communications (GSM), North American digital cellular (NADC), extended-time division multiple access (E-TDMA), and/or wide band code division multiple access (WCDMA), etc. The memory 730 of the electronic device 700 may include a semiconductor device according to the above-described embodiments.

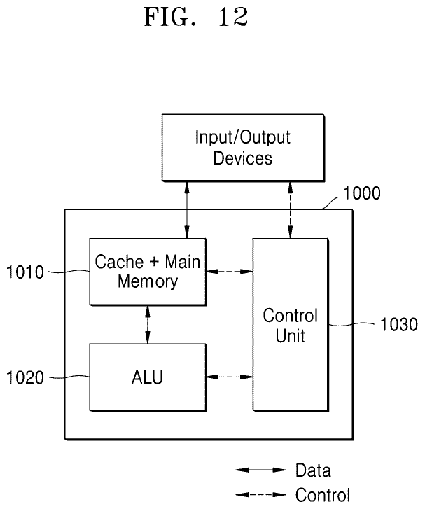

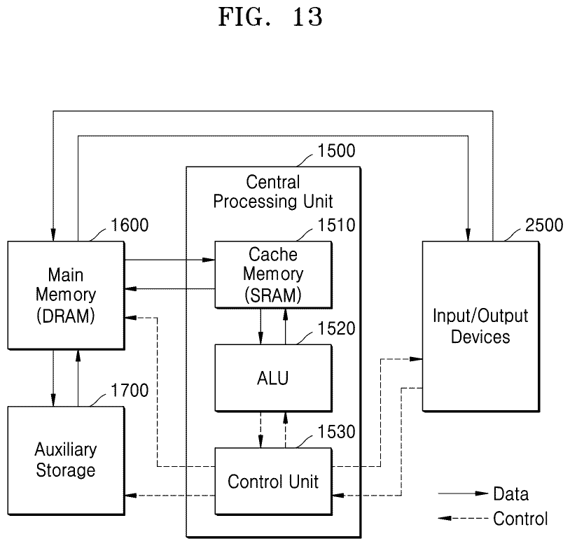

FIGS. 12 and 13 are conceptual views schematically showing a device architecture applicable to an electronic device according to an embodiment.

Referring to FIG. 12, an electronic device architecture 1000 may include a memory unit 1010 and a control unit 1030 and may further include an arithmetic logic unit (ALU) 1020. The memory unit 1010, the ALU 1020, and the control unit 1030 may be electrically connected to one another. For example, the electronic device architecture 1000 may be implemented as one chip including the memory unit 1010, the ALU 1020, and the control unit 1030. More specifically, the memory unit 1010, the ALU 1020, and the control unit 1030 may communicate directly by being connected to one another through a metal line on-chip. The memory unit 1010, the ALU 1020, and the control unit 1030 may be monolithically integrated on one substrate to form one chip. An input/output device 2000 may be connected to the electronic device architecture (chip) 1000. The memory unit 1010 may include both a main memory and a cache memory. The electronic device architecture (chip) 1000 may be an on-chip memory processing unit. Each of the memory unit 1010, the ALU 1020, and/or the control unit 1030 may independently include a semiconductor device according to the above-described embodiments.

Referring to FIG. 13, a cache memory 1510, an ALU 1520, and a control unit 1530 may constitute a central processing unit (CPU) 1500, and the cache memory 1510 may include a static random access memory (SRAM). A main memory 1600 and an auxiliary storage 1700 may be included in addition to the CPU 1500, and an input/output device 2500 may also be included. The main memory 1600 may be, for example, a dynamic random access memory (DRAM), and may include a semiconductor device according to the above-described embodiments.

Depending on a circumstance, the electronic device architecture may be implemented in a form where computing-unit devices and memory-unit devices are adjacent to each other in one chip, without distinction of sub-units. Although the embodiments have been described above, these are merely examples and various changes may be made therefrom by those of ordinary skill in the art.

While the above-described semiconductor devices and the electronic devices including the same have been described with reference to the embodiments described in the drawings, it will be understood by those of ordinary skill in the art that various modifications and equivalent other embodiments are possible therefrom. Therefore, the disclosed embodiments should be considered in a descriptive sense rather than a restrictive sense. The scope of the present specification is not described above, but in the claims, and all the differences in a range equivalent thereto should be interpreted as being included.

The semiconductor device according to an embodiment may have superior performance even in a small thickness of about 1 nm or less and reduce a short channel effect, by using the 2D semiconductor material as a channel layer, thereby overcoming the limitation of performance degradation caused by size reduction of the semiconductor device.

Moreover, the semiconductor device according to an embodiment may include a doped extension portion of the channel layer by using charge transfer through an adjacent material, i.e., an insulating layer. The doped extension portion of the channel layer may contribute to performance improvement of the semiconductor device.

Due to a difference in dielectric constant (permittivity) between a first insulating layer and a second insulating layer included in the semiconductor device according to an embodiment, capacitance interference between source/drain electrodes and a gate electrode may be minimized, thus minimizing a leakage current.

Although the embodiments have been described above, these are merely examples and various changes may be made therefrom by those of ordinary skill in the art.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer comprising a two-dimensional (2D) semiconductor material, a channel portion, and an extension portion on both sides of the channel portion;
a source electrode and a drain electrode on both sides of the channel layer, respectively;
a gate electrode surrounding the channel portion;
a first insulating layer between the channel portion of the channel layer and the gate electrode; and
a second insulating layer on the extension portion of the channel layer, a material of the second insulating layer being different than a material of the first insulating layer, wherein
the second insulating layer comprises at least one of an n-type dopant or a p-type dopant, and
a dopant in the extension portion is the same as a dopant in the second insulating layer.

2. The semiconductor device of claim 1, wherein
the first insulating layer surrounds the channel portion, and
the second insulating layer surrounds the extension portion.

3. The semiconductor device of claim 1, wherein the second insulating layer comprises at least one of an aluminum oxide, a hafnium oxide, a zirconium oxide, or a combination thereof.

4. The semiconductor device of claim 1, wherein the second insulating layer comprises an insulating material having a dielectric constant less than a dielectric constant of the first insulating layer.

5. The semiconductor device of claim 1, wherein the second insulating layer comprises an insulating material having a band offset of about 200 meV or less with the 2D semiconductor material.

6. The semiconductor device of claim 1, wherein the second insulating layer comprises an insulating material having a band offset of about 50 meV or greater with the 2D semiconductor material.

7. The semiconductor device of claim 1, wherein the channel layer comprises two or more channel layers.

8. The semiconductor device of claim 1, further comprising:
at least one supporting layer on the channel layer.

9. The semiconductor device of claim 8, wherein the supporting layer comprises at least one of a hafnium oxide or an aluminum oxide.

10. The semiconductor device of claim 1, wherein the 2D semiconductor material comprises an n-type semiconductor material or a p-type 2D semiconductor material.

11. The semiconductor device of claim 10, wherein the n-type 2D semiconductor material comprises at least one of MoS₂, MoSe₂, MoTe₂, or WS₂.

12. The semiconductor device of claim 10, wherein the p-type 2D semiconductor material comprises at least one of WSe₂, MoTe₂, or PtSe₂.

13. The semiconductor device of claim 1, wherein the 2D semiconductor material comprises transition metal dichalcogenide (TMD).

14. The semiconductor device of claim 13, wherein
the TMD comprises one of molybdenum (Mo), tungsten (W), niobium (Nb), vanadium (V), tantalum (Ta), titanium (Ti), zirconium (Zr), hafnium (Hf), technetium (Tc), and rhenium (Re), and a chalcogen element selected from sulfur (S), selenium (Se), and tellurium (Te).

15. The semiconductor device of claim 1, wherein the 2D semiconductor material comprises black phosphorus.

16. A semiconductor device comprising:
a channel layer comprising a two-dimensional (2D) semiconductor material, a channel portion, and an extension portion on both sides of the channel portion;
a source electrode and a drain electrode on both sides of the channel layer, respectively;
a gate electrode on the channel portion;
a first insulating layer between the channel portion of the channel layer and the gate electrode; and
a second insulating layer on the extension portion of the channel layer, wherein
a material of the second insulating layer is different from a material of the first insulating layer.

17. The semiconductor device of claim 16, wherein the second insulating layer comprises an insulating material having a band offset of about 200 meV or less with the 2D semiconductor material.

18. The semiconductor device of claim 16, wherein the second insulating layer comprises an insulating material having a band offset of about 50 meV or greater with the 2D semiconductor material.

19. An electronic device comprising:
the semiconductor device according to claim 16.
